(19) United States
(12) Patent Application Publication
(10) Pub. No.: US 2024/0396354 A1
(43) Pub. Date: Nov. 28, 2024

(54) DISPLAY DEVICE AND OPERATING METHOD THEREOF

(71) Applicant: LG ELECTRONICS INC., Seoul (KR)

(72) Inventor: Deok Yong CHUNG, Seoul (KR)

(73) Assignee: LG ELECTRONICS INC., Seoul (KR)

(21) Appl. No.: 18/387,384

(22) Filed: Nov. 6, 2023

(30) Foreign Application Priority Data
May 25, 2023 (KR) 10-2023-0067676

(51) Int. Cl. H02J 7/00

(52) U.S. Cl. CPC H02J 7/00714; H02J 7/00304; H02J 7/0031; H02J 7/0049; H02J 2310/22

(57) ABSTRACT

Disclosed is a display device including a power supply circuit configured to charge a battery by supplying a charging current to the battery and a controller configured to obtain a remaining battery capacity by sensing the charging current, and set an exclusion interval of the charging current, the exclusion interval being not reflected in the remaining battery capacity.

### CROSS-REFERENCE TO RELATED APPLICATION

Pursuant to 35 U.S.C. § 119, this application claims the benefit of earlier filing date and right of priority to Korean Application No. 10-2023-0067676, filed on May 25, 2023, the contents of which are all incorporated by reference herein in its entirety.

### BACKGROUND OF THE INVENTION

### 1. Field of the Invention

The present disclosure relates to a display device. In particular, the present disclosure relates to a display device for accurately providing a remaining battery capacity.

### 2. Discussion of the Related Art

Recently, the functions of terminal are being diversified. For example, there are functions for data and voice communication, photo and video shooting through a camera, voice recording, music file playback through a speaker system, and output of images or videos to a display.

Some terminals add an electronic game play function or perform a multimedia player function.

As the functions of the terminal are diversified, the terminal is implemented with, for example, in the form of a multimedia device (Multimedia player) equipped with complex functions such as shooting still pictures or moving pictures, reproducing music or video files, playing games, receiving broadcasts, or the like.

Meanwhile, such a terminal may be supplied with power wirelessly. That is, power may be supplied from a battery for the terminal. Accordingly, the user can freely move and use the terminal. The user can estimate the available time or charge the battery by checking the battery level displayed on the screen.

Accordingly, demand for a function for accurately measuring and displaying the remaining battery capacity is increasing.

### SUMMARY OF THE INVENTION

An object of the display device of the present disclosure is to minimize inconvenience due to the remaining battery capacity being provided differently from an actual remaining battery capacity.

Another object of the display device of the present disclosure is to minimize a problem in which the remaining battery capacity is integrated while a battery is not being charged.

A display device according to an embodiment of the present disclosure may include a power supply circuit configured to charge a battery by supplying a charging current to the battery and a controller configured to obtain a remaining battery capacity by sensing the charging current, and set an exclusion interval of the charging current, the exclusion interval being not reflected in the remaining battery capacity.

A display device according to an embodiment of the present disclosure may set an exclusion interval based on a sensing error range of a charging current.

A display device according to an embodiment of the present disclosure may set the exclusion interval within the sensing error range based on a point at which the charging current is 0 mA.

A display device according to an embodiment of the present disclosure may set an interval between a point at which a charging current is 0 mA and a point at which the charging current is at a maximum value of a sensing error range as an exclusion interval.

A display device according to an embodiment of the present disclosure may set at least a portion of an interval in which a charging current is less than a cutoff current as an exclusion interval.

A display device according to an embodiment of the present disclosure may set an interval between a point at which a charging current is less than a cutoff current and a point at which the charging current is 0 mA as an exclusion interval.

A display device according to an embodiment of the present disclosure may divide a charging current into a plurality of operating intervals based on a state of the display device, and set an exclusion interval to at least a portion of an interval other than the plurality of operating intervals.

A display device according to an embodiment of the present disclosure, a state of the display device includes a charging state and a battery protection state, and a controller may set an exclusion interval to at least a portion of a charging current between an interval corresponding to the charging state and an interval corresponding to the battery protection state.

A display device according to an embodiment of the present disclosure, a state of the display device includes a battery protection state and a full charge state, and a controller may set an exclusion interval to at least a portion of the charging current between an interval corresponding to the battery protection state and an interval corresponding to the full charge state.

A display device according to an embodiment of the present disclosure, a state of the display device includes a battery usage state, and a controller may correct and display a remaining battery capacity when a predetermined time has elapsed after the battery usage state ends.

A display device according to an embodiment of the present disclosure may set an exclusion interval based on at least one of a capacity of the battery, a magnitude of a sensing resistance through which the charging current flows, performance of a sensor which measures the charging current, and a temperature of the battery.

The display device according to the embodiment of the present disclosure can accurately provide a remaining battery capacity.

The display device according to the embodiment of the present disclosure can minimize the occurrence of an error in the remaining battery capacity.

### BRIEF DESCRIPTION OF THE DRAWINGS

FIG. 1 is a block diagram showing a configuration of a display device according to an

embodiment of the present disclosure.

FIG. 2 is a block diagram of a remote control device according to an embodiment of the present disclosure.

FIG. 3 shows an actual configuration example of a remote control device 200 according to an embodiment of the present disclosure.

FIG. 4 shows an example of using a remote control device according to an embodiment of the present disclosure.

FIGS. 5A and 5B are diagrams for describing a horizontal mode and a vertical mode of a stand-type display device according to an embodiment of the present disclosure.

FIG. 6 is a diagram for describing a method for obtaining a remaining battery capacity in a display device according to an embodiment of the present disclosure.

FIG. 7 is a graph showing a relationship between a charging current and a battery voltage according to a battery charging time of a display device according to an embodiment of the present disclosure.

FIG. 8 is a graph showing a charging current according to an operating state of a display device according to an embodiment of the present disclosure.

FIG. 9 is a flowchart for describing a method of testing whether a display device obtains a remaining battery capacity without reflecting an exclusion interval according to an embodiment of the present disclosure.

FIG. 10 shows a correction table for correcting the remaining battery capacity of the display device according to an embodiment of the present disclosure.

### DETAILED DESCRIPTION OF THE PREFERRED EMBODIMENTS

Hereinafter, embodiments of the present disclosure will be described in detail with reference to the drawings. The suffixes “module” and “unit or portion” for components used in the following description are merely provided only for facilitation of preparing this specification, and thus they are not granted a specific meaning or function.

The display device according to an embodiment of the present disclosure is, for example, an intelligent display device in which a computer support function is added to a broadcast reception function, and is faithful to a broadcast reception function and has an Internet function added thereto, such as a handwritten input device, a touch screen Alternatively, a more user-friendly interface such as a spatial remote control may be provided. In addition, it is connected to the Internet and a computer with the support of a wired or wireless Internet function, so that functions such as e-mail, web browsing, banking, or games can also be performed. A standardized general-purpose OS may be used for these various functions.

Accordingly, in the display device described in the present disclosure, various user-friendly functions can be performed because various applications can be freely added or deleted, for example, on a general-purpose OS kernel. More specifically, the display device may be, for example, a network TV, HBBTV, smart TV, LED TV, OLED TV, and the like, and may be applied to a smart phone in some cases.

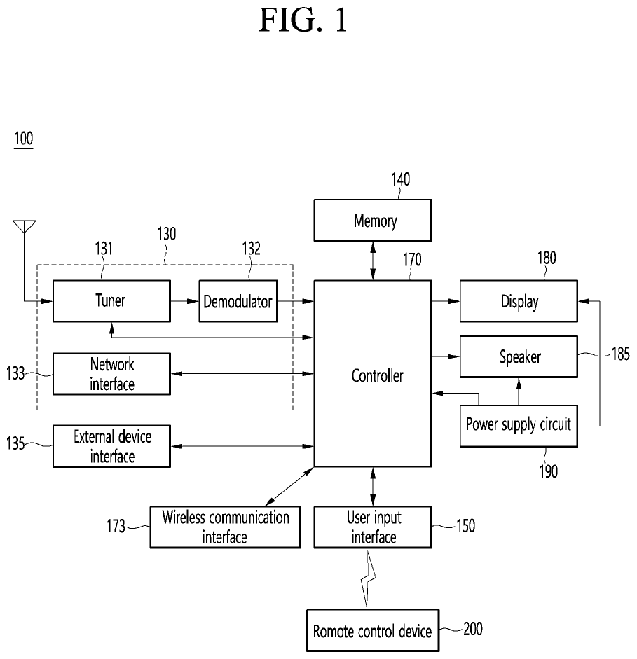

FIG. 1 is a block diagram showing a configuration of a display device according to an embodiment of the present disclosure.

Referring to FIG. 1, a display device 100 may include a broadcast receiver 130, an external device interface 135, a memory 140, a user input interface 150, a controller 170, a wireless communication interface 173, a display 180, a speaker 185, and a power supply circuit 190.

The broadcast receiving unit 130 may include a tuner 131, a demodulator 132, and a network interface 133.

The tuner 131 may select a specific broadcast channel according to a channel selection command. The tuner 131 may receive a broadcast signal for the selected specific broadcast channel.

The demodulator 132 may separate the received broadcast signal into an image signal, an audio signal, and a data signal related to a broadcast program, and restore the separated image signal, audio signal, and data signal to a format capable of being output.

The external device interface 135 may receive an application or a list of applications in an external device adjacent thereto, and transmit the same to the controller 170 or the memory 140.

The external device interface 135 may provide a connection path between the display device 100 and an external device. The external device interface 135 may receive one or more of images and audio output from an external device connected to the display device 100 in a wired or wireless manner, and transmit the same to the controller 170. The external device interface 135 may include a plurality of external input terminals. The plurality of external input terminals may include an RGB terminal, one or more High Definition Multimedia Interface (HDMI) terminals, and a component terminal.

The image signal of the external device input through the external device interface unit 135 may be output through the display 180. The audio signal of the external device input through the external device interface 135 may be output through the speaker 185.

The external device connectable to the external device interface 135 may be any one of a set-top box, a Blu-ray player, a DVD player, a game machine, a sound bar, a smartphone, a PC, a USB memory, and a home theater, but this is only an example.

The network interface 133 may provide an interface for connecting the display device 100 to a wired/wireless network including an Internet network. The network interface 133 may transmit or receive data to or from other users or other electronic devices through a connected network or another network linked to the connected network.

In addition, a part of content data stored in the display device 100 may be transmitted to a selected user among a selected user or a selected electronic device among other users or other electronic devices registered in advance in the display device 100.

The network interface 133 may access a predetermined web page through the connected network or the other network linked to the connected network. That is, it is possible to access a predetermined web page through a network, and transmit or receive data to or from a corresponding server.

In addition, the network interface 133 may receive content or data provided by a content provider or a network operator. That is, the network interface 133 may receive content such as movies, advertisements, games, VOD, and broadcast signals and information related thereto provided from a content provider or a network provider through a network.

In addition, the network interface 133 may receive update information and update files of firmware provided by the network operator, and may transmit data to an Internet or content provider or a network operator.

The network interface 133 may select and receive a desired application from among applications that are open to the public through a network.

The memory 140 may store programs for signal processing and control of the controller 170, and may store images, audio, or data signals, which have been subjected to signal-processed.

In addition, the memory 140 may perform a function for temporarily storing images, audio, or data signals input from an external device interface 135 or the network interface 133, and store information on a predetermined image through a channel storage function.

The memory 140 may store an application or a list of applications input from the external device interface 135 or the network interface 133.

The display device 100 may play back a content file (a moving image file, a still image file, a music file, a document file, an application file, or the like) stored in the memory 140 and provide the same to the user.

The user input interface 150 may transmit a signal input by the user to the controller 170 or a signal from the controller 170 to the user. For example, the user input interface 150 may receive and process a control signal such as power on/off, channel selection, screen settings, and the like from the remote control device 200 in accordance with various communication methods, such as a Bluetooth communication method, a WB (Ultra Wideband) communication method, a ZigBee communication method, an RF (Radio Frequency) communication method, or an infrared (IR) communication method or may perform processing to transmit the control signal from the controller 170 to the remote control device 200.

In addition, the user input interface 150 may transmit a control signal input from a local key (not shown) such as a power key, a channel key, a volume key, and a setting value to the controller 170.

The image signal image-processed by the controller 170 may be input to the display 180 and displayed as an image corresponding to a corresponding image signal. Also, the image signal image-processed by the controller 170 may be input to an external output device through the external device interface 135.

The audio signal processed by the controller 170 may be output to the speaker 185. Also, the audio signal processed by the controller 170 may be input to the external output device through the external device interface 135.

In addition, the controller 170 may control the overall operation of the display device 100.

In addition, the controller 170 may control the display device 100 by a user command input through the user input interface 150 or an internal program and connect to a network to download an application a list of applications or applications desired by the user to the display device 100.

The controller 170 may allow the channel information or the like selected by the user to be output through the display 180 or the speaker 185 along with the processed image or audio signal.

In addition, the controller 170 may output an image signal or an audio signal through the display 180 or the speaker 185, according to a command for playing back an image of an external device through the user input interface 150, the image signal or the audio signal being input from an external device, for example, a camera or a camcorder, through the external device interface 135.

Meanwhile, the controller 170 may allow the display 180 to display an image, for example, allow a broadcast image which is input through the tuner 131 or an external input image which is input through the external device interface 135, an image which is input through the network interface unit or an image which is stored in the memory 140 to be displayed on the display 180. In this case, an image being displayed on the display 180 may be a still image or a moving image, and may be a 2D image or a 3D image.

In addition, the controller 170 may allow content stored in the display device 100, received broadcast content, or external input content input from the outside to be played back, and the content may have various forms such as a broadcast image, an external input image, an audio file, still images, accessed web screens, and document files.

The wireless communication interface 173 may communicate with an external device through wired or wireless communication. The wireless communication interface 173 may perform short range communication with an external device. To this end, the wireless communication interface 173 may support short range communication using at least one of Bluetooth™, Radio Frequency Identification (RFID), Infrared Data Association (IrDA), Ultra Wideband (UWB), ZigBee, Near Field Communication (NFC), Wi-Fi (Wireless-Fidelity), Wi-Fi (Wireless-Fidelity), Wi-Fi Direct, and Wireless USB (Wireless Universal Serial Bus) technologies. The wireless communication interface 173 may support wireless communication between the display device 100 and a wireless communication system, between the display device 100 and another display device 100, or between the display device 100 and a network in which the display device 100 (or an external server) is located through wireless area networks. The wireless area networks may be wireless personal area networks.

Here, the another display device 100 may be a wearable device (e.g., a smartwatch, smart glasses or a head mounted display (HMD), a mobile terminal such as a smart phone, which is able to exchange data (or interwork) with the display device 100 according to the present disclosure. The wireless communication interface 173 may detect (or recognize) a wearable device capable of communication around the display device 100.

Furthermore, when the detected wearable device is an authenticated device to communicate with the display device 100 according to the present disclosure, the controller 170 may transmit at least a portion of data processed by the display device 100 to the wearable device through the wireless communication interface 173. Therefore, a user of the wearable device may use data processed by the display device 100 through the wearable device.

The display 180 may convert image signals, data signals, and OSD signals processed by the controller 170, or image signals or data signals received from the external device interface 135 into R, G, and B signals, and generate drive signals.

Meanwhile, since the display device 100 shown in FIG. 1 is only an embodiment of the present disclosure, some of the illustrated components may be integrated, added, or omitted depending on the specification of the display device 100 that is actually implemented.

That is, two or more components may be combined into one component, or one component may be divided into two or more components as necessary. In addition, a function performed in each block is for describing an embodiment of the present disclosure, and its specific operation or device does not limit the scope of the present disclosure.

According to another embodiment of the present disclosure, unlike the display device 100 shown in FIG. 1, the display device 100 may receive an image through the network interface 133 or the external device interface 135 without a tuner 131 and a demodulator 132 and play back the same.

For example, the display device 100 may be divided into an image processing device, such as a set-top box, for receiving broadcast signals or content according to various network services, and a content playback device that plays back content input from the image processing device.

In this case, an operation method of the display device according to an embodiment of the present disclosure will be described below may be implemented by not only the display device 100 as described with reference to FIG. 1 and but also one of an image processing device such as the separated set-top box and a content playback device including the display 180 the audio output unit 185.

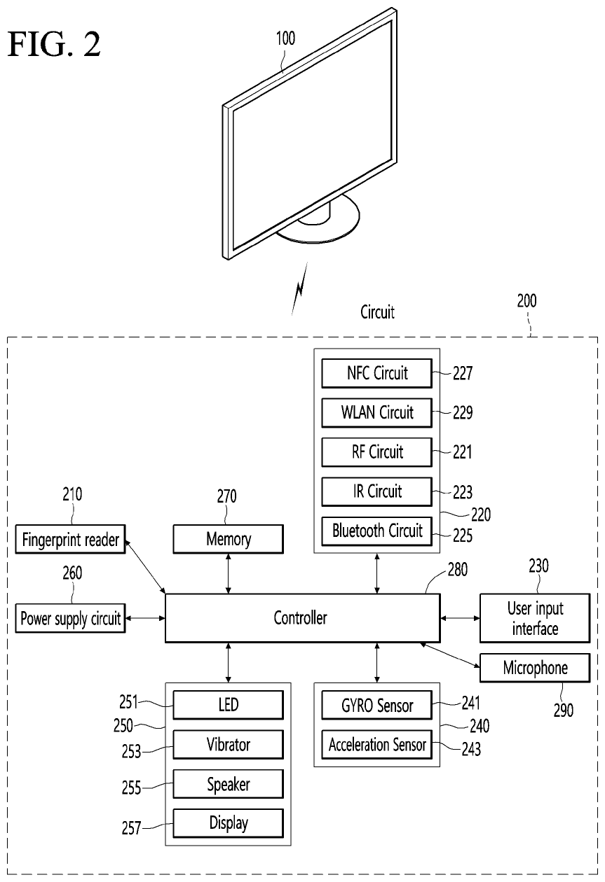

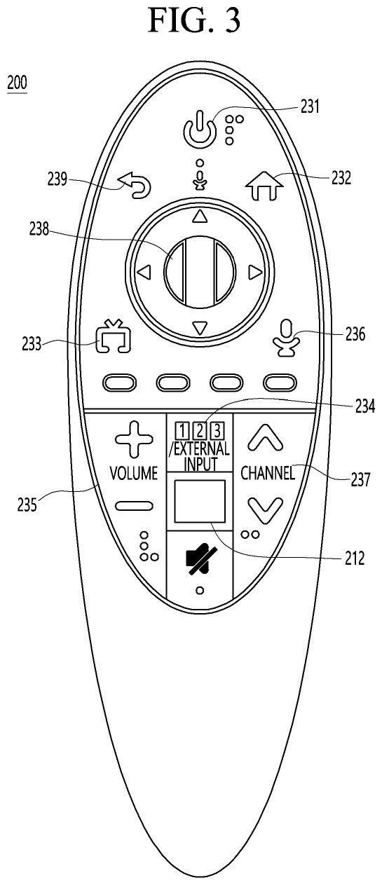

Next, a remote control device according to an embodiment of the present disclosure will be described with reference to FIGS. 2 to 3.

FIG. 2 is a block diagram of a remote control device according to an embodiment of the present disclosure, and FIG. 3 shows an actual configuration example of a remote control device 200 according to an embodiment of the present disclosure.

First, referring to FIG. 2, the remote control device 200 may include a fingerprint reader 210, a wireless communication circuit 220, a user input interface 230, a sensor 240, an output interface 250, a power supply circuit 260, a memory 270, a controller 280, and a microphone 290.

Referring to FIG. 2, the wireless communication circuit 220 may transmit and receive signals to and from any one of display devices according to embodiments of the present disclosure described above.

The remote control device 200 may include an RF circuit 221 capable of transmitting and receiving signals to and from the display device 100 according to the RF communication standard, and an IR circuit 223 capable of transmitting and receiving signals to and from the display device 100 according to the IR communication standard. In addition, the remote control device 200 may include a Bluetooth circuit 225 capable of transmitting and receiving signals to and from the display device 100 according to the Bluetooth communication standard. In addition, the remote control device 200 may include an NFC circuit 227 capable of transmitting and receiving signals to and from the display device 100 according to the NFC (near field communication) communication standard, and a WLAN circuit 229 capable of transmitting and receiving signals to and from the display device 100 according to the wireless LAN (WLAN) communication standard.

In addition, the remote control device 200 may transmit a signal containing information on the movement of the remote control device 200 to the display device 100 through the wireless communication circuit 220.

In addition, the remote control device 200 may receive a signal transmitted by the display device 100 through the RF circuit 221, and transmit a command regarding power on/off, channel change, volume adjustment, or the like to the display device 100 through the IR circuit 223 as necessary.

The user input interface 230 may include a keypad, a button, a touch pad, a touch screen, or the like. The user may input a command related to the display device 100 to the remote control device 200 by operating the user input interface 230. When the user input interface 230 includes a hard key button, the user may input a command related to the display device 100 to the remote control device 200 through a push operation of the hard key button. Details will be described with reference to FIG. 3.

Referring to FIG. 3, the remote control device 200 may include a plurality of buttons. The plurality of buttons may include a fingerprint recognition button 212, a power button 231, a home button 232, a live button 233, an external input button 234, a volume control button 235, a voice recognition button 236, a channel change button 237, an OK button 238, and a back-play button 239.

The fingerprint recognition button 212 may be a button for recognizing a user's fingerprint. In one embodiment, the fingerprint recognition button 212 may enable a push operation, and thus may receive a push operation and a fingerprint recognition operation.

The power button 231 may be a button for turning on/off the power of the display device 100.

The home button 232 may be a button for moving to the home screen of the display device 100.

The live button 233 may be a button for displaying a real-time broadcast program.

The external input button 234 may be a button for receiving an external input connected to the display device 100.

The volume control button 235 may be a button for adjusting the level of the volume output by the display device 100.

The voice recognition button 236 may be a button for receiving a user's voice and recognizing the received voice.

The channel change button 237 may be a button for receiving a broadcast signal of a specific broadcast channel.

The OK button 238 may be a button for selecting a specific function, and the back-play button 239 may be a button for returning to a previous screen.

A description will be given referring again to FIG. 2.

When the user input interface 230 includes a touch screen, the user may input a command related to the display device 100 to the remote control device 200 by touching a soft key of the touch screen. In addition, the user input interface 230 may include various types of input means that may be operated by a user, such as a scroll key or a jog key, and the present embodiment does not limit the scope of the present disclosure.

The sensor 240 may include a gyro sensor 241 or an acceleration sensor 243, and the gyro sensor 241 may sense information regarding the movement of the remote control device 200.

For example, the gyro sensor 241 may sense information about the operation of the remote control device 200 based on the x, y, and z axes, and the acceleration sensor 243 may sense information about the moving speed of the remote control device 200. Meanwhile, the remote control device 200 may further include a distance measuring sensor to sense the distance between the display device 100 and the display 180.

The output interface 250 may output an image or audio signal corresponding to the operation of the user input interface 230 or a signal transmitted from the display device 100.

The user may recognize whether the user input interface 230 is operated or whether the display device 100 is controlled through the output interface 250.

For example, the output interface 450 may include an LED 251 that emits light, a vibrator 253 that generates vibration, a speaker 255 that outputs sound, or a display 257 that outputs an image when the user input interface 230 is operated or a signal is transmitted and received to and from the display device 100 through the wireless communication unit 225.

In addition, the power supply circuit 260 may supply power to the remote control device 200, and stop power supply when the remote control device 200 has not moved for a predetermined time to reduce power consumption.

The power supply circuit 260 may restart power supply when a predetermined key provided in the remote control device 200 is operated.

The memory 270 may store various types of programs and application data required for control or operation of the remote control device 200.

When the remote control device 200 transmits and receives signals wirelessly through the display device 100 and the RF circuit 221, the remote control device 200 and the display device 100 transmit and receive signals through a predetermined frequency band.

The controller 280 of the remote control device 200 may store and refer to information on a frequency band capable of wirelessly transmitting and receiving signals to and from the display device 100 paired with the remote control device 200 in the memory 270.

The controller 280 may control all matters related to the control of the remote control device 200. The controller 280 may transmit a signal corresponding to a predetermined key operation of the user input interface 230 or a signal corresponding to the movement of the remote control device 200 sensed by the sensor 240 through the wireless communication unit 225.

Also, the microphone 290 of the remote control device 200 may obtain a speech.

A plurality of microphones 290 may be provided.

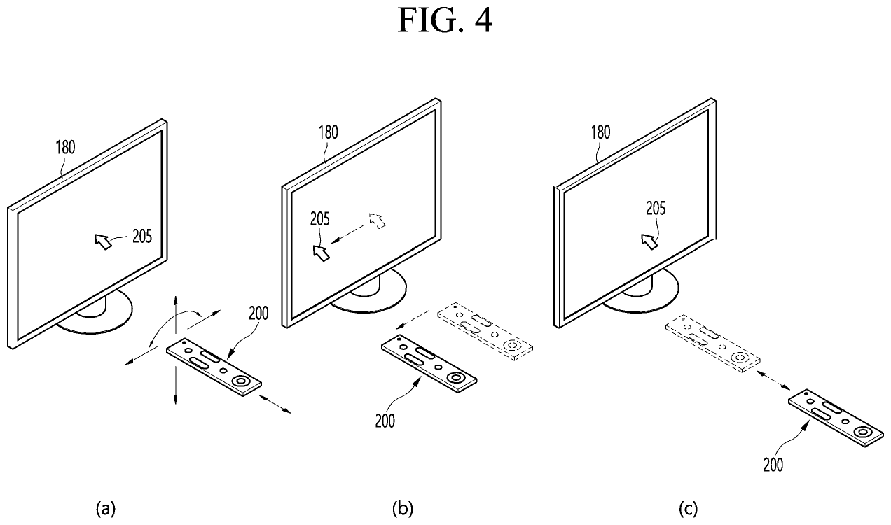

Next, a description will be given referring to FIG. 4.

FIG. 4 shows an example of using a remote control device according to an embodiment of the present disclosure.

In FIG. 4, (a) illustrates that a pointer 205 corresponding to the remote control device 200 is displayed on the display 180.

The user may move or rotate the remote control device 200 up, down, left and right. The pointer 205 displayed on the display 180 of the display device 100 may correspond to the movement of the remote control device 200. As shown in the drawings, the pointer 205 is moved and displayed according to movement of the remote control device 200 in a 3D space, so the remote control device 200 may be called a space remote control device.

In (b) of FIG. 4, it is illustrated that that when the user moves the remote control device 200 to the left, the pointer 205 displayed on the display 180 of the display device 100 moves to the left correspondingly.

Information on the movement of the remote control device 200 detected through a sensor of the remote control device 200 is transmitted to the display device 100. The display device 100 may calculate the coordinates of the pointer 205 based on information on the movement of the remote control device 200. The display device 100 may display the pointer 205 to correspond to the calculated coordinates.

In (c) of FIG. 4, it is illustrated that a user moves the remote control device 200 away from the display 180 while pressing a specific button in the remote control device 200. Accordingly, a selected area in the display 180 corresponding to the pointer 205 may be zoomed in and displayed enlarged.

Conversely, when the user moves the remote control device 200 to be close to the display 180, the selected area in the display 180 corresponding to the pointer 205 may be zoomed out and displayed reduced.

On the other hand, when the remote control device 200 moves away from the display 180, the selected area may be zoomed out, and when the remote control device 200 moves to be close to the display 180, the selected area may be zoomed in.

Also, in a state in which a specific button in the remote control device 200 is being pressed, recognition of up, down, left, or right movements may be excluded. That is, when the remote control device 200 moves away from or close to the display 180, the up, down, left, or right movements are not recognized, and only the forward and backward movements may be recognized. In a state in which a specific button in the remote control device 200 is not being pressed, only the pointer 205 moves according to the up, down, left, or right movements of the remote control device 200.

Meanwhile, the movement speed or the movement direction of the pointer 205 may correspond to the movement speed or the movement direction of the remote control device 200.

Meanwhile, in the present specification, a pointer refers to an object displayed on the display 180 in response to an operation of the remote control device 200. Accordingly, objects of various shapes other than the arrow shape shown in the drawings are possible as the pointer 205. For example, the object may be a concept including a dot, a cursor, a prompt, a thick outline, and the like. In addition, the pointer 205 may be displayed corresponding to any one point among points on a horizontal axis and a vertical axis on the display 180, and may also be displayed corresponding to a plurality of points such as a line and a surface.

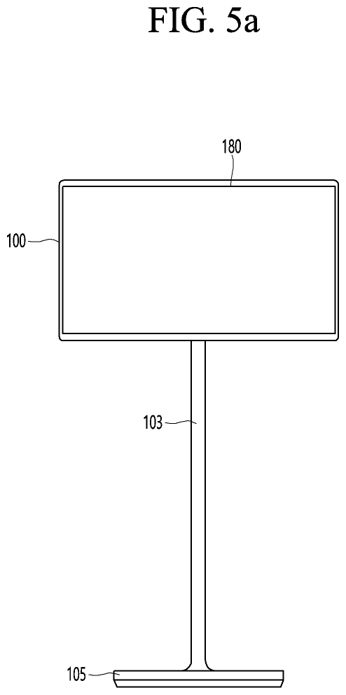

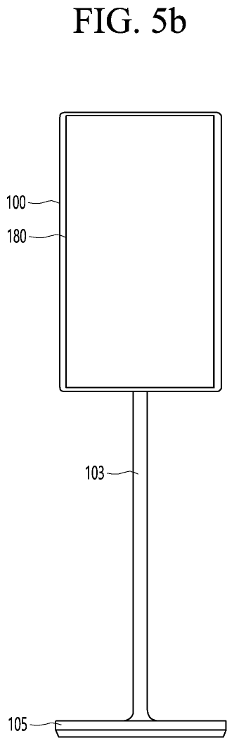

FIGS. 5A and 5B are diagrams for describing a horizontal mode and a vertical mode of a stand-type display device according to an embodiment of the present disclosure.

Referring to FIGS. 5A and 5B, a stand-type display device 100 is illustrated.

A shaft 103 and a stand base 105 may be connected to the display device 100.

The shaft 103 may connect the display device 100 and the stand base 105 to each other. The shaft 103 may extend vertically.

The lower end of the shaft 103 may be connected to the edges of the stand base 105.

The lower end of the shaft 103 may be rotatably connected to the edges of the stand base 105.

The display device 100 and the shaft 103 may rotate about a vertical axis with respect to the stand base 105.

An upper portion of the shaft 103 may be connected to the rear surface of the display device 100.

The stand base 105 may serve to support the display device 100.

The display device 100 may be configured to include the shaft 103 and the stand base 105.

The display device 100 may rotate around a point where the upper portion of the shaft 103 and the rear surface of the display 180 contact each other.

FIG. 5A shows that the display 180 operates in a landscape mode in which the horizontal length is greater than the vertical length, and FIG. 5B shows that the display 180 operates in a portrait mode in which the vertical length is greater than the horizontal length.

A user may move while holding a stand-type display device. That is, the stand-type display device has improved mobility, unlike a fixed device, so that a user is not limited by an arrangement position.

To this end, the display device 100 may include a battery to receive power wirelessly. The controller 170 may display a remaining battery capacity on the display device 180. Accordingly, the user can identify the remaining battery capacity to estimate a usable time or charge the battery.

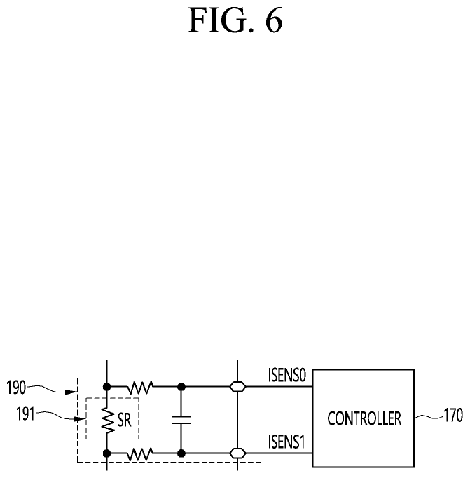

Next, referring to FIG. 6, a method for obtaining a remaining battery capacity in a display device according to an embodiment of the present disclosure will be described.

FIG. 6 is a diagram for describing a method for obtaining a remaining battery capacity in a display device according to an embodiment of the present disclosure.

The display device 100 may include some or all of a controller 170 and a power supply circuit 190.

The power supply circuit 190 may charge a battery by supplying a charging current to the battery. The power supply circuit 190 may include a sensing resistance 191.

The sensing resistance 191 may be a resistance for sensing the charging current for charging the battery. The current flowing through the sensing resistance 191 may be a charging current for charging the battery.

The controller 170 may serve as a battery management system (BMS). The BMS may be a system that entirely manages the battery. The BMS may predict a state of charge (SOC) or life of the battery by measuring at least one of a voltage, current, and temperature of the battery. In addition, the BMS may perform various roles such as minimizing a deviation between battery cells or preventing overdischarge of the battery.

The controller 170 may obtain the remaining battery capacity by sensing the charging current. The remaining battery capacity may be a ratio of the charged capacity to the total capacity of the battery.

The controller 170 may sense the charging current flowing through the sensing resistance 191. The controller 170 may obtain the remaining battery capacity by integrating the sensed charging current. Specifically, the controller 170 may estimate the SOC by integrating a charging current during a charge/discharge cycle of the battery with respect to an initial value of the battery SOC.

The controller 170 may display the obtained remaining battery capacity on the display 180.

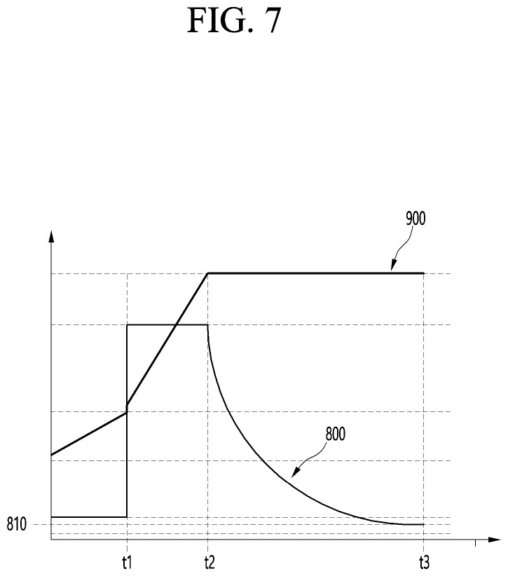

Next, the relationship between the charging current and the battery voltage will be described with reference to FIG. 7.

FIG. 7 is a graph showing a relationship between a charging current and a battery voltage according to a battery charging time of a display device according to an embodiment of the present disclosure.

A battery charging time may include a charging start point t1, a maximum voltage point t2, and a charging end point t3.

The charging start point t1 may be a point when battery charging is started. The maximum voltage point t2 may be a point when the battery voltage 900 reaches the maximum voltage. The charging end point t3 may be a point in time when the battery is fully charged and charging of the battery is ended.

The charging current 800 may have a maximum charging current from the charging start point t1 to the maximum voltage point t2. Also, the battery voltage 900 may increase from the charging start point t1 to the maximum voltage point t2.

The charging current 800 may decrease from the maximum voltage point t2 to the charging end point t3. In addition, the battery voltage 900 may have the maximum voltage from the maximum voltage point t2 to the charging end point t3.

Meanwhile, when the battery is fully charged, a current may not flow into the battery. Accordingly, when the battery is fully charged, the charging current 800 may be 0 mA.

However, the charging end point t3 may be a point before the charging current 800 has reached 0 mA. Accordingly, overcharging of the battery may be prevented or the charging time may be shortened.

The charging current 800 at the charging end point t3 may be a cut-off current 700. The cut-off current 700 may be a full charge declaration current. The cut-off current 810 may be a current set to terminate charging to prevent overcharging of the battery or to shorten the charging time.

For example, the cut-off current 810 may be set to 310 mA, but is not limited thereto. The cut-off current 810 may be set in various ways according to the type of battery, a maximum charging current, and the type of an external power source.

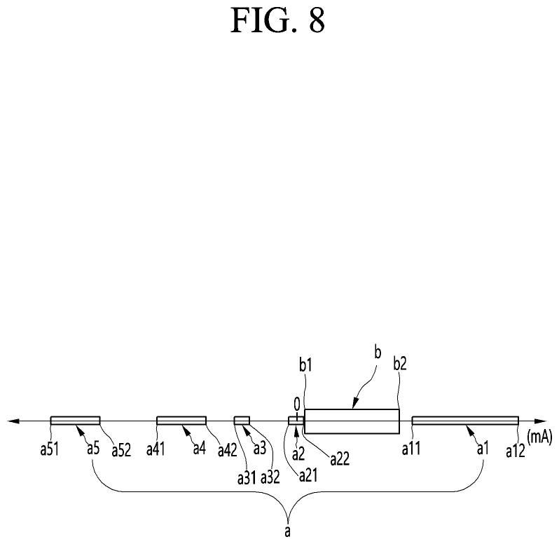

Summarizing FIG. 8, the battery voltage may be maintained or increased while the battery is being charged. Additionally, the charge current may be maintained or decreased while the battery is being charged.

Meanwhile, the charging current 800 after the charging end point t3 may be 0 mA. The charge current 800 while the battery is not being charged may be 0 mA.

However, an error may occur in the charging current sensed by the controller 170 according to various factors such as performance of the controller 170, an input voltage, a battery temperature, and the like.

For example, the controller 170 may sense the charging current by dividing the voltage of the sensing resistance 191 by the magnitude of the sensing resistance 191. Accordingly, the sensing error of the charging current may occur due to the sensing error of the voltage of the sensing resistance 191.

Specifically, the sensing error of the voltage of the sensing resistance 191 obtained by the controller 170 may occur according to the input voltage or the battery temperature.

For example, the voltage of the sensing resistance 191 obtained by the controller 170 may have a sensing error in the range of ±25 uV. In this case, when the charging current is 0 mA and the magnitude of the sensing resistance 191 is 1 mΩ, the charging current sensed by the controller 170 may have a value in the range of ±25 uV/1 mΩ. That is, the range of the sensing error of the charging current 800 may be ±25 mA.

Accordingly, when the actual charging current 800 is 0 mA, the charging current may be sensed as a value other than 0 mA, such as 10 mA. In this case, the controller 170 may integrate the sensed charging current. Accordingly, the remaining battery capacity obtained by the controller 170 may be greater than the actual remaining battery capacity.

That is, the remaining battery capacity displayed by the controller 170 may be greater than the actual remaining battery capacity. For example, the total battery voltage when the actual battery capacity is 100% may be 16.4V. However, when the charging current is erroneously integrated due to a sensing error, the remaining battery capacity may be displayed as 100% even when the total battery voltage is 14.548V less than 16V.

When the total battery voltage is 14.548V, the battery may be discharged in a shorter time than when the total battery voltage is 16V. Accordingly, there is a problem in that a user may perceive that a usage time is reduced compared to the displayed remaining battery capacity.

Therefore, the display device 100 according to an embodiment of the present disclosure aims to accurately provide the remaining battery capacity by preventing the integration of the charging current due to the sensing error.

To this end, the display device 100 according to an embodiment of the present disclosure may set an exclusion interval of the charging current, which is not reflected in the remaining battery capacity.

When the sensed charge current has a value within the exclusion interval, the controller 170 may not integrate the sensed charge current.

The controller 170 may set the exclusion interval in various ways.

The controller 170 may set the exclusion interval based on the range of the sensing error of the charging current.

The sensing error range may vary depending on the capacity of the battery, the magnitude of the sensing resistance 191 through which the charging current flows, the performance of measuring the charging current, the temperature of the battery, and the like. Accordingly, the controller 170 may set the exclusion interval based on at least one of the capacity of the battery, the magnitude of the sensing resistance 191 through which the charging current flows, the performance of measuring the charging current, and the temperature of the battery.

The controller 170 may set a interval within a sensing error range as an exclusion interval based on a point where the charging current is 0 mA. For example, when the sensing error range is ±25 mA, the controller 170 may set an interval in which the charging current is from −25 mA to +25 mA, as the exclusion interval. Accordingly, when the charging current is 0 mA, the controller 170 may minimize a problem in which the charging current is integrated due to a sensing error.

The controller 170 may set an interval between a point where the charging current is 0 mA and a point where the charging current is the maximum value of the sensing error range, as the exclusion interval. For example, when the sensing error range is ±25 mA, the controller 170 may set an interval between a point where the charging current is 0 mA and a point where the charging current is +25 mA, as the exclusion interval. As the display device 100 is used, the battery is discharged and the charging current may have a negative number. Accordingly, the controller 170 may set the exclusion interval by excluding a charging current interval corresponding to the usage of the display device 100. Accordingly, the controller 170 may accurately obtain the remaining battery capacity that changes according to the usage of the display device 100. The controller 170 may set at least a portion of an interval in which the charging current is

less than the cut-off current as the exclusion interval. Alternatively, the controller may set at least a portion of an interval in which the charging current is greater than 0 mA and is less than the cut-off current as the exclusion interval. As described above, since the controller 170 may stop charging the battery when the cut-off current is reached, an interval in which the charging current is less than the cut-off current may be a current interval in which the battery is not charged. Accordingly, the controller 170 may set at least a portion of the interval in which the charging current is less than the cut-off current as the exclusion interval, thereby minimizing the problem of the charging current being integrated when the battery is not being charged.

Meanwhile, the display device 100 according to an embodiment of the present disclosure may set an exclusion interval in consideration of a charging current according to an operating state of the display device 100.

Details will be described with reference to FIG. 8.

FIG. 8 is a graph showing a charging current according to an operating state of a display device according to an embodiment of the present disclosure.

With respect to a point where the charging current is 0 mA, the right area may mean a state in which current flows into a battery. In addition, it may mean that the current flowing into the battery increases as it moves to the right in the area of the graph.

With respect to a point where the charging current is 0 mA, the left area may mean a state in which current flows out of the battery. In addition, it may mean that the current flowing out of the battery increases as it moves to the left in the area of the graph.

The controller 170 may divide the charging current into a plurality of operating intervals (a) based on the operating state of the display device 100.

The operating state of the display device 100 may include some or all of a charging state, a battery protection state, a full charge state, a standby state, and a battery usage state.

The charging current may be divided into intervals a1, a2, a3, a4, and a5 corresponding to the charging state, the battery protection state, the full charge state, the standby state, and the battery usage state.

The charging state may be a state in which the battery is being charged using an AC power source. The display device 100 may be connected to the AC power source to receive a charging current for charging a battery from the AC power source. Therefore, the charging current in the charging state may have a positive value. For example, the start point a11 of the interval a1 corresponding to the charging state may be 310 mA, and the end point a12 may be 1800 mA.

The battery protection state may be a state in which a charging current is cut off to protect the battery. The interval a2 corresponding to the protection state may be an interval including 0 mA. Alternatively, the interval a2 corresponding to the protection state may be an interval in which the start point a21 and the end point a22 are the same and the start point a21 and the end point a22 both are 0 mA, but this is only an example and is not limited thereto.

The full charge state may be a state in which the battery is fully charged and an AC power source is connected to the display device 100. In the fully charge state, the charging current may have a negative number due to the current consumption of the battery. For example, the start point a31 of the interval a3 corresponding to the full charge state may be −8 mA and the end point a32 may be −9 mA.

The standby state may be a state in which the AC power source is not connected to the display device 100 but the display device 100 is not in use. Since the AC power source is not connected to the display device 100, the charging current in the standby state may have a larger value in a negative direction than the charging current in the fully charge state. For example, the start point a41 of the interval a4 corresponding to the full charge state may be −25 mA and the end point a42 may be −16 mA.

The battery usage state may be a state in which the AC power source is not connected and the display device 100 is in use with the power of the battery. Since the display device 100 is in use with the power of the battery, the charging current in the battery usage state may have a larger value in the negative direction than the charging current in the standby state. The start point a51 of the interval a5 corresponding to the battery usage state may be −2500 mA and the end point a52 may be −1500 mA, but this is merely an example and is not limited thereto.

Intervals other than the plurality of operating intervals (a) may not be charging current intervals according to actual use of the display device 100. That is, an interval other than the plurality of operating intervals (a) may be an interval in which battery charging/discharging is not actually made.

Accordingly, the controller 170 may set at least a portion of the intervals other than the plurality of operation intervals (a) as the exclusion interval (b).

For example, the controller 170 may set at least a portion of the charging current between the interval a1 corresponding to the charging state and the interval a2 corresponding to the battery protection state as the exclusion interval (b).

Alternatively, the controller 170 may set at least a portion of the charging current between the interval a2 corresponding to the battery protection state and the interval a3 corresponding to the full charge state as an exclusion interval.

In addition, the controller 170 may set the start point b1 and the end point b2 of the exclusion interval (b) in various ways.

Summarizing FIG. 8, the display device 100 according to an embodiment of the present disclosure may set at least a portion of an interval other than the plurality of intervals (a) corresponding to the operating states of the display device 100 as the exclusion interval (b), thus the exclusion interval being not be reflected in the remaining battery capacity.

Accordingly, it is possible to obtain an accurate remaining battery capacity by preventing integration of the charging current in an interval where the remaining battery capacity does not actually change.

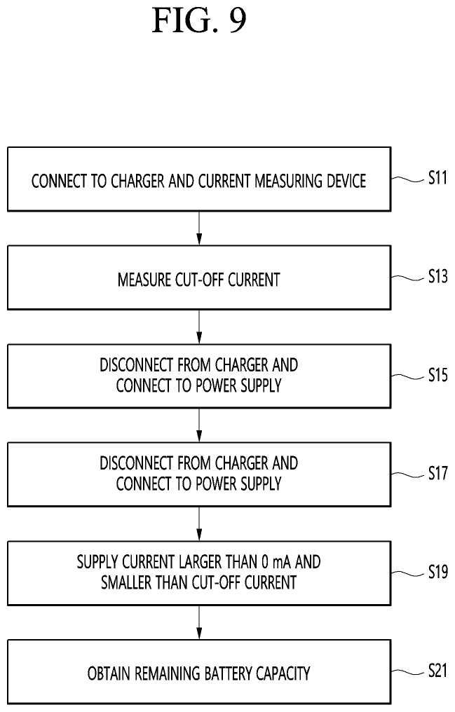

FIG. 9 is a flowchart for describing a method of testing whether a display device obtains a remaining battery capacity without reflecting an exclusion interval according to an embodiment of the present disclosure.

Specifically, FIG. 9 shows a flowchart for describing a test method when the controller 170 sets an interval where the charging current is greater than 0 mA and less than the cut-off current as the exclusion interval.

The display device 100 may be connected to a charger and a current measuring device (S11).

The charger may be a device connected to the display device 100 to charge the battery. For example, the charger may be an AC power source connected to the display device 100.

The current measuring device may be a device for measuring a current supplied to the battery. For example, the current measuring device may be a multimeter.

The current measuring device may measure a cut-off current (S13).

The cut-off current may be a current at a charging end point. The current measuring device may obtain the cut-off current by measuring a current at the charging end point.

The display device 100 may be disconnected from the charger. Also, the display device 100 may be connected to a power supply (S17).

The power supply may be a device capable of forcibly introducing a charging current into the battery of the display device 100.

The power supply may supply a current larger than 0 mA and smaller than the cut-off current to the display device 100 (S19).

The current supplied to the display device 100 by the power supply may be a current within the exclusion interval.

The controller 170 may obtain the remaining battery capacity (S21).

When the remaining battery capacity obtained by the controller 170 changes, it may mean that the current in the exclusion interval is integrated.

On the other hand, when the remaining battery capacity does not change, it may mean that the current in the exclusion interval is not integrated.

According to the method described with reference to FIG. 9, it is possible to determine whether or not the display device 100 according to an embodiment of the present disclosure obtains the remaining battery capacity by integrating a current in the exclusion interval.

Meanwhile, the display device 100 according to an embodiment of the present disclosure may prevent an error in the remaining battery capacity and correct the error in the remaining battery capacity after occurrence of the error.

The battery usage state may be a state in which a user continuously viewing the display 180 such as watching content. When the remaining battery capacity is corrected and displayed while the user viewing the display 180, reliability for the remaining battery capacity may be lowered.

In order to prevent this, the controller 170 may correct and display the remaining battery capacity when a preset time has elapsed after the battery usage state is ended. The preset time may be set to a time interval in which use of the display device 100 is finished and the user is not looking at the display 180. However, it is appropriate that the method of setting the preset time is not limited thereto.

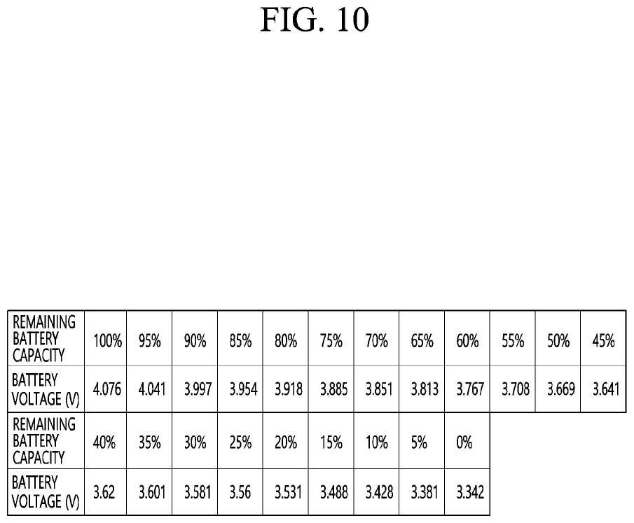

A method of correcting the remaining battery capacity obtained by the display device 100 according to an embodiment of the present disclosure will be described with reference to FIG. 10.

FIG. 10 shows a correction table for correcting the remaining battery capacity of the display device according to an embodiment of the present disclosure.

The correction table may include a remaining battery capacity and a battery voltage corresponding to the remaining battery capacity.

Referring to the example of FIG. 10, a battery voltage when the battery of one cell is 100% charged may be 4.076V. The controller 170 may obtain a remaining battery capacity as 100% when the battery voltage is obtained as 4.076V.

Meanwhile, there may be a possibility in which the remaining battery capacity obtained by the controller 170 is 100%, but the battery voltage is 9.997V. In this case, the controller 170 may correct the remaining battery capacity to 90% corresponding to 3.997%.

Referring to FIG. 10, the display device 100 according to an embodiment of the present disclosure may correct the remaining battery capacity using the battery voltage.

Accordingly, the display device 100 according to an embodiment of the present disclosure may prevent an error in the remaining battery capacity and correct the remaining battery capacity after occurrence of the error. Accordingly, the display device 100 according to an embodiment of the present disclosure may obtain and display the remaining battery capacity more accurately.

According to an embodiment of the present disclosure, the above-described method may be implemented with codes readable by a processor on a medium in which a program is recorded. Examples of the medium readable by the processor include a ROM (Read Only Memory), a Random Access Memory (RAM), a CD-ROM, a magnetic tape, a floppy disk, an optical data storage device, and the like.

The above-described display device is not limited to the configuration and method of the above-described embodiments, but the embodiments may be configured by selectively combining all or part of each embodiment such that various modifications can be made.

What is claimed is:

1. A display device comprising:
a power supply circuit configured to charge a battery by supplying a charging current to the battery; and
a controller configured to obtain a remaining battery capacity by sensing the charging current, and set an exclusion interval of the charging current, the exclusion interval being not reflected in the remaining battery capacity.

2. The display device according to claim 1, wherein the controller is configured to set the exclusion interval based on a sensing error range of the charging current.

3. The display device according to claim 2, wherein the controller is configured to set the exclusion interval within the sensing error range based on a point at which the charging current is 0 mA.

4. The display device according to claim 3, wherein the controller is configured to set an interval between a point at which the charging current is 0 mA and a point at which the charging current is at a maximum value of the sensing error range as the exclusion interval.

5. The display device according to claim 1, wherein the controller is configured to set at least a portion of an interval in which the charging current is less than a cutoff current as the exclusion interval.

6. The display device according to claim 5, wherein the controller is configured to set an interval between a point at which the charging current is less than the cutoff current and a point at which the charging current is 0 mA as the exclusion interval.

7. The display device according to claim 1, wherein the controller is configured to divide the charging current into a plurality of operating intervals based on a state of the display device, and set the exclusion interval to at least a portion of an interval other than the plurality of operating intervals.

8. The display device according to claim 7, wherein the state of the display device includes a charging state and a battery protection state, and
wherein the controller is configured to set the exclusion interval to at least a portion of the charging current between an interval corresponding to the charging state and an interval corresponding to the battery protection state.

9. The display device according to claim 8, wherein the state of the display device includes a battery protection state and a full charge state, and
wherein the controller is configured to set the exclusion interval to at least a portion of the charging current between the interval corresponding to the battery protection state and an interval corresponding to the full charge state.

10. The display device according to claim 8, wherein the state of the display device includes a battery usage state, and
wherein the controller is configured to correct and display the remaining battery capacity when a predetermined time has elapsed after the battery usage state ends.

11. The display device according to claim 1, wherein the controller is configured to set the exclusion interval based on at least one of a capacity of the battery, a magnitude of a sensing resistance through which the charging current flows, performance of a sensor which measures the charging current, and a temperature of the battery.
